(19) United States
(12) Patent Application Publication
(10) Pub. No.: US 2025/0068814 A1
(43) Pub. Date: Feb. 27, 2025

(54) INSTRUMENTATION-ASSISTED EMULATION DEBUG OF ASPECT-ORIENTED HARDWARE WITH MIXED LEVELS OF ABSTRACTION

(71) Applicant: International Business Machines Corporation, Armonk, NY (US)

(72) Inventors: Arun Joseph, Kadugodi (IN); Sampath Goud Baddam, CV Ramannager (IN); Pradeep Joy, Thrissur (IN); Melchizedek Das, Paradeep (IN); Joachim Heiner Paret, Ehningen (DE); Matthias Klein, Poughkeepsie, NY (US); Bodo Hoppe, Ingersheim (DE); Wolfgang Roesner, Austin, TX (US)

(21) Appl. No.: 18/455,083

(22) Filed: Aug. 24, 2023

(51) Int. Cl. G06F 30/3308; G06F 30/323

(52) U.S. Cl. CPC G06F 30/3308; G06F 30/323

(57) ABSTRACT

A computer-implemented method for instrumentation-assisted debugging is provided. The computer-implemented method includes compiling a hardware design to generate a compiled design, generating, from the compiled design, code for the hardware design and debug assist elements, feeding the code into a vendor emulation flow that outputs a vendor waveform and transforming the vendor waveform into a logic simulation waveform that is compatible with a hardware design language (HDL) using the debug assist elements for hardware logic debugging.

### BACKGROUND

The present invention generally relates to computing technology, and more specifically, to efficient instrumentation-assisted emulation debug of aspect-oriented hardware with mixed levels of abstraction.

Various feature-rich tools are available for software development to write, compile, debug, execute and test computer programs. Some tools also facilitate collaboration between multiple software developers, for example, providing version control, code control and other such features.

### SUMMARY

Embodiments of the present invention are directed to a computer-implemented method for instrumentation-assisted debugging. The computer-implemented method includes compiling a hardware design to generate a compiled design, generating, from the compiled design, code for the hardware design and debug assist elements, feeding the code into a vendor emulation flow that outputs a vendor waveform and transforming the vendor waveform into a logic simulation waveform that is compatible with a hardware design language (HDL) using the debug assist elements for hardware logic debugging.

An execution of the computer-implemented method for instrumentation-assisted debugging provides for aspect-oriented co-debug of simulation traces from different simulators, emulators, post-silicon debug for mixed language (VHDL/Verilog/other) and mixed level of abstraction designs.

Embodiments of the present invention are directed to a computer program product for instrumentation-assisted debugging. The computer program product includes one or more computer readable storage media having computer readable program code collectively stored on the one or more computer readable storage media. The computer readable program code is executed by a processor of a computer system to cause the computer system to perform a method. The method includes compiling a hardware design to generate a compiled design, generating, from the compiled design, code for the hardware design and debug assist elements, feeding the code into a vendor emulation flow that outputs a vendor waveform and transforming the vendor waveform into a logic simulation waveform compatible with a hardware design language (HDL) using the debug assist elements for hardware logic debugging.

Embodiments of the present invention are directed to a computing system including a processor, a memory coupled to the processor and one or more computer readable storage media coupled to the processor. The one or more computer readable storage media collectively contain instructions that are executed by the processor via the memory to cause the processor to perform steps for instrumentation-assisted debugging. The steps for instrumentation-assisted debugging include compiling a hardware design to generate a compiled design, generating, from the compiled design, code for the hardware design and debug assist elements, feeding the code into a vendor emulation flow that outputs a vendor waveform and transforming the vendor waveform into a logic simulation waveform compatible with a hardware design language (HDL) using the debug assist elements for hardware logic debugging.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a schematic diagram of a computing environment for executing a computer-implemented method for selectively capturing traffic in a service mesh to simulate and address an issue with a service invoke chain in accordance with one or more embodiments of the present invention;

FIG. 2 depicts a set of disjoint tools used by logic designers;

FIG. 3 depicts a block diagram of a logic design system;

FIG. 4 depicts a block diagram of a session;

FIG. 5 depicts a flowchart of using a session for logic design and verification;

FIG. 6 depicts a flow diagram illustrating an operation of a platform for collaborative hardware logic design and debug;

FIG. 7 depicts a flow diagram illustrating a computer-implemented method for instrumentation-assisted debugging in accordance with one or more embodiments of the present invention; and

FIG. 8 depicts a flow diagram illustrating an operation of a platform for aspect-oriented co-debug of simulation traces from different simulators, emulators, post-silicon debug for mixed language (VHDL/Verilog/other) and mixed level of abstraction designs in accordance with one or more embodiments of the present invention;

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the disclosed embodiments, the various elements illustrated in the figures are provided with two or three digit reference numbers. With minor exceptions, the leftmost digit(s) of each reference number correspond to the figure in which its element is first illustrated.

### DETAILED DESCRIPTION

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

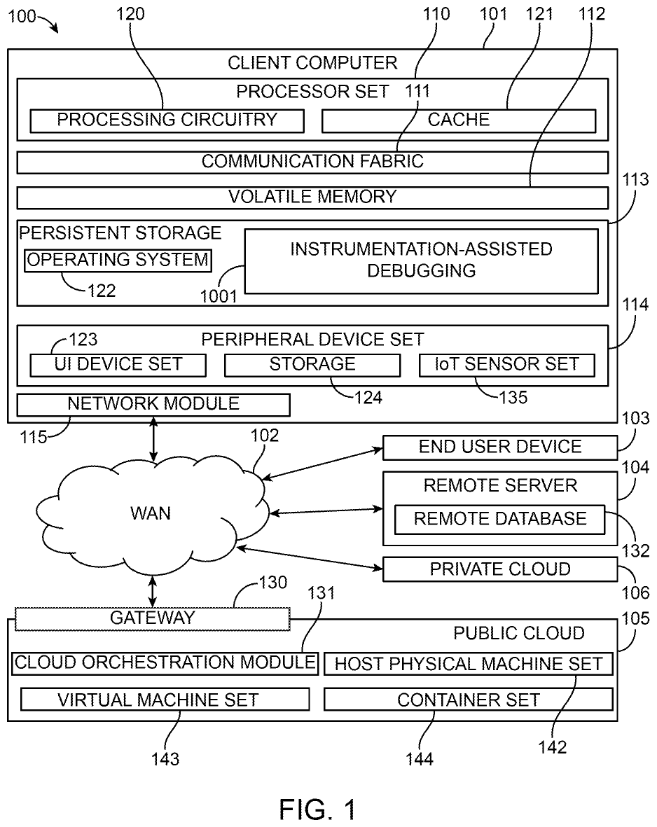

With reference to FIG. 1, a computer or computing device 100 that implements a computer-implemented method for instrumentation-assisted debugging in accordance with one or more embodiments of the present invention is provided. The computer or computing device 100 of FIG. 1 contains an example of an environment for the execution of at least some of the computer code involved in performing the inventive methods, such as the block 1001 of the computer-implemented method for instrumentation-assisted debugging. In addition to the computer-implemented method for instrumentation-assisted debugging of block 1001, the computer or computing device 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and the computer-implemented method of block 1001, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

The computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of the computer-implemented method, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

The processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In the computer-implemented method, at least some of the instructions for performing the inventive methods may be stored in the block 1001 of the computer-implemented method in persistent storage 113.

Communication fabric 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in the block 1001 of the computer-implemented method typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Turning now to an overview of technologies that are more specifically relevant to aspects of the invention, a typical workflow for circuit design starts with a logic design and functional verification. Logic design, also referred to as logic synthesis, is a process by which a specification of desired circuit behavior is turned into a design implementation in terms of logic gates. The specification can also be updated in this logic design phase. The logic design can result in a design of the circuit at a register transfer level (RTL). Common examples of such outputs include designs specified in hardware description languages, including VHSIC hardware description language (VHDL), Verilog, etc. Functional verification is the task of verifying that the logic design conforms to the specification. Functional verification is known to be a technical challenge because of the sheer volume of possible test-cases that exist in even a simple design. Various techniques are used to address the functional verification. These include logic simulation (simulates the logic), emulation (software system to replicate the logic), formal verification (mathematical proof), intelligent verification (automation to adapt to changes in the RTL), heuristics, etc.

Once the logic design is generated and verified, custom implementation and digital implementation can be performed. Custom implementation includes creating a prototype of the circuit whereas digital implementation includes creating a digital emulator/simulator of the circuit. The custom implementation includes producing a circuit using gates, wires and other hardware components.

Either the custom implementation, or the digital implementation, or both are analyzed to determine whether the design meets timing and power targets that were set in the specification. Further, the testability of the custom and design implementations is checked and, depending on the testability, design for testing (DFT) is performed to add testability features to a hardware product design. The added features make it easier to develop and apply manufacturing tests to the designed hardware. The purpose of manufacturing tests includes validating that the product hardware contains no manufacturing defects that could adversely affect the product's correct functioning.

The workflow for the circuit design can also include checking if the design of the circuit is manufacturable and if it meets all rules set by manufacturing. Once the design is deemed manufacturable, a package is designed for the circuit and the designed package is used for manufacturing the circuit.

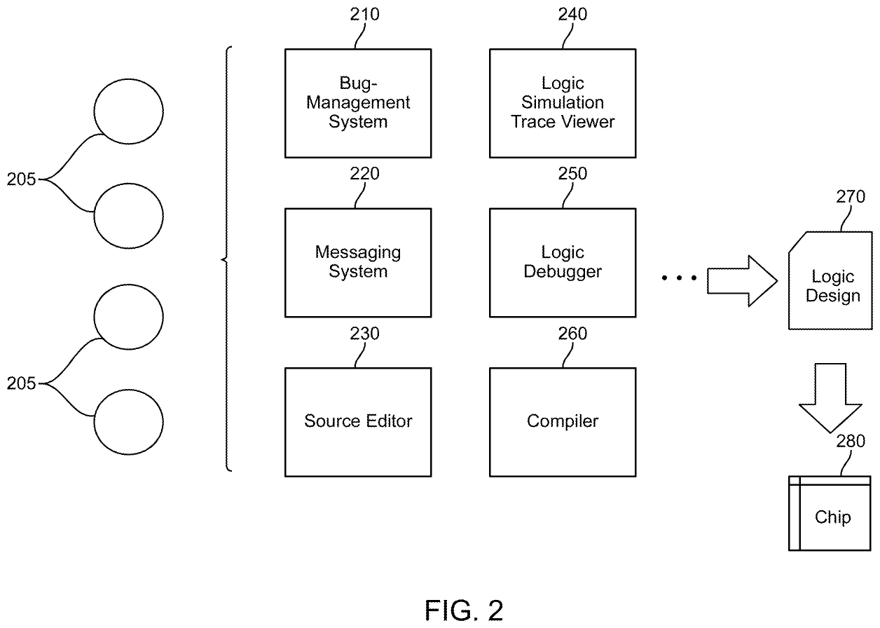

Typically, logic design and functional verification is the most resource-consuming phase of the hardware design workflow, where resources include time, money, people, etc. At present, for logic design and functional verification, the logic designers use a varied and disjoint set of tools. With reference to FIG. 2, a set of such disjoint tools used by logic designers is illustrated. As shown in FIG. 2, several logic designers 205 are depicted, all working towards creating a logic design 270, which gets manufactured into one or more circuit chips 280. The logic designers 205 can use tools, which are all computer program products, such as a source editor 230, a compiler 260, a messaging system 220, a logic debugger 250, a bug-management system 210, a logic simulation trace viewer 240 and other such tools. For example, logic designers 205 can use editors 230 such as Emacs, VI, Notepad++, or any other source editor to type their computer programs, for example, using programming languages like VHDL, Verilog, RTL, etc. The logic designers 205 can compile these programs using one or more compilers 260 for the programming language used. Further, the logic designers 205 can debug the programs using the logic debugger 250, and record information about an identified defect (“bug”) in the bug-management system 210. In some cases, the logic designers 205 can share information about the identified defect(s) with each other using messaging system 220, such as email, instant messaging, etc. In these or other cases, a first logic designer 205, upon receiving such notification from a second logic designer 205 (or any other testing personnel), can use a logic simulation trace viewer 240 to trace the execution of the logic design 270 to reproduce the defect at his/her end in order to repair/debug the logic design 270.

Because all these tools are disjointed, state retention of the overall system is usually unavailable. Here, a “state” represents a hardware debug state that identifies one or more parameters and other configurations of the logic design 270 of the hardware at which a defect has been identified. Because of the lack of such state retention, the first logic designer 205 in the above example, who receives the defect notification, has to set up the hardware state of the logic design 270 to reproduce the defect. Recreating a particular set up for the defect to be reproduced may not be possible in typical cases, because of the large number of factors involved. Further, because of the several disjoint tools involved, which can be different for different logic designers 205, the reproducibility of the defect can be more challenging. Additionally, in the case where the logic designers 205 are geographically distributed, conveying a hardware debug state to another logic designer 205 can be challenging given the large number of factors involved.

The issues laid out above have been addressed by using microservices that facilitate using the tools used for logic design and verification to be executed as microservices within “sessions” that, in turn, facilitate state retention. Such retained states of the session can be shared with logic designers 205 (or other personnel) to allow reproducibility of a specific state of the hardware represented by the logic design 270. In turn, a logic designer 205 can debug or perform other operations from a provided state.

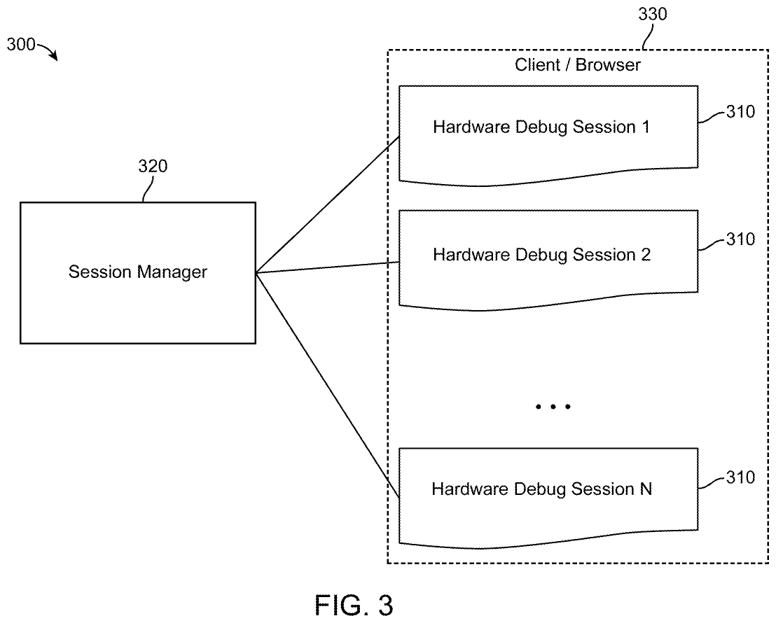

With reference to FIG. 3, a logic design system 300 is provided as a foundational electronic design automation (EDA) logic design platform that uses services, such as microservices to implement one or more functions that the logic designers 205 used for generating the logic design 270 in FIG. 2. The services are scalable. The logic design system 300 facilitates aspect-oriented hardware design and debugging. Aspect-oriented hardware design (AOD) is a paradigm that aims to increase modularity by allowing the separation of cross-cutting concerns when developing a hardware design. AOD facilitates including/using source code that can be useful for the logic designers 205 to complete the logic design and verification, but which is not part of the final logic design 270 (and in turn the chip 280) of FIG. 2. For example, in addition to main functions of the hardware, additional aspects can be clocking, power, test and trace.

As shown in FIG. 3, the logic design system 300 includes one or more sessions 310 that are all managed by a session manager 320. The sessions 310 can be part of a client application 330 that is coupled with the session manager 310. The session manager 320 and the client application 330 can be part of a single user interface window, or two separate user interface windows. Each session 310 can have its own user interface window, which is displayed inside the client application 330. While FIG. 3 depicts a view of a particular logic designer 205, different logic designers 205 can have a different number of sessions 310 open concurrently and the logic designer 205 can switch between one session 310 to another session 310.

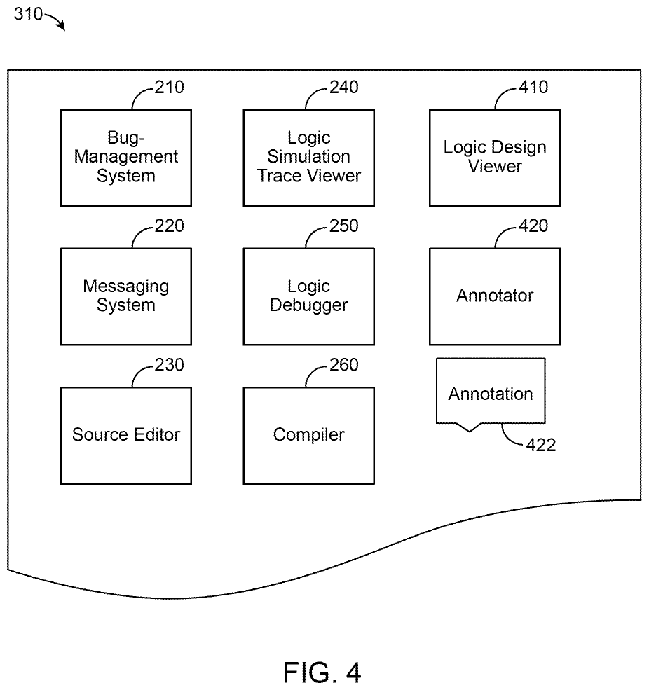

With continued reference to FIGS. 2 and 3 and with additional reference to FIG. 4, a session 310 can include a set of applications (i.e., computer programs) that are pre-configured and contained. The applications are microservices, web services or other types of programs that can be executed within a container, which is a standard unit of software that packages an executable environment for one or more applications. The container includes an entire runtime environment: the application, plus all its dependencies, libraries and other binaries and configuration files needed to run the application bundled into one package. The session 310 can include one or more of the tools (see FIG. 2) that the logic designer 205 uses for the logic design and verification. The tools are executed as microservices in session 310. This facilitates the logic design system 300 to provide interactions between one or more tools that are being used inside session 310. For example, the selection of one or more elements in one tool, for example, the source editor 230, can trigger the selection of corresponding element(s) in another tool, for example, the logic simulation trace viewer 240. The session 310 can also include a logic design viewer 410 and an annotator 420. The logic design viewer 410 can show a hierarchical view of one or more source codes, for example, files that are part of the logic design. For example, the source code files can be a collection of VHDL and/or other programming language files. The logic designer 205 can select and open (in the source editor 230, for example) one or more of the source code files via the logic design viewer 410. The annotator 420 facilitates the logic designer 205 to annotate one or more elements of the logic design in the present session 310. For example, the annotator 420 can provide one or more user interface elements that allow the logic designer 205 to type or record a note 422. The note 422 is associated with the present session 310 and is not visible in any other session 310. The note 422 can also be associated with one or more elements from the several elements of the logic design 270 being interacted with in session 310 where the element can include one or more instructions from the source code, a portion of a simulation trace, a clock diagram of the operation of the circuit represented by the logic design or any other such element.

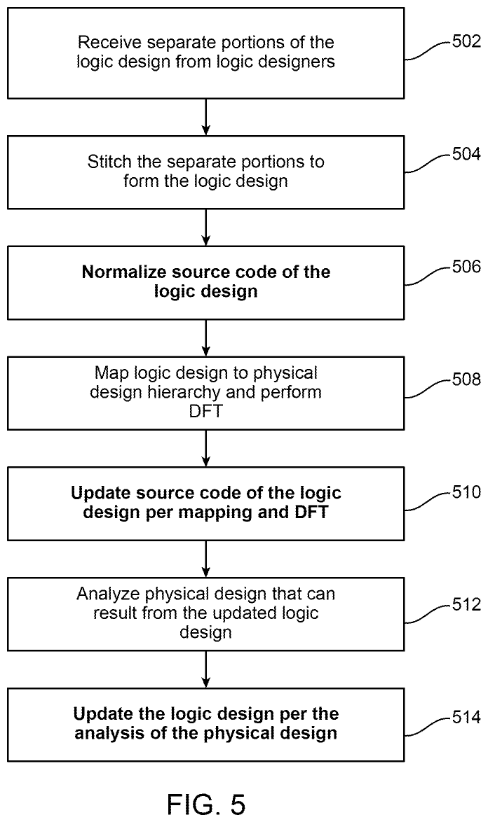

With reference to FIG. 5, a session for logic design and verification includes receiving separate portions of the logic design 270 from the different logic designers 205 who are creating the logic design (see FIG. 2) at block 502. The portions of the logic design 270 can be received as separate source code (e.g., VHDL, Verilog, etc.) files. The received portions of the logic design 270 are stitched together at block 504. The stitching can include compiling the source code in a specific sequence to facilitate outputs from a module in the logic design being used by one or more other modules. A normalized source code, such as a normalized VHDL, is created from the received separate portions of the logic design at block 506. The normalization can include aggregating common source code and/or modules that may be implemented by different logic designers 205, removing redundancies and applying a common syntactic context so that variables, parameters, function names, macros and other such elements from the logic design 270 follow a specific convention. The logic design 270 is then mapped to a physical design hierarchy and DFT can be performed at block 508 and source code of the logic design 270 is updated based on one or more defects identified during the mapping and DFT at block 510. The physical design that can result from the updated logic design 270 is analyzed at block 512 and one or more defects can be detected based on such analysis with the logic design 270 further updated to correct such defects at block 514.

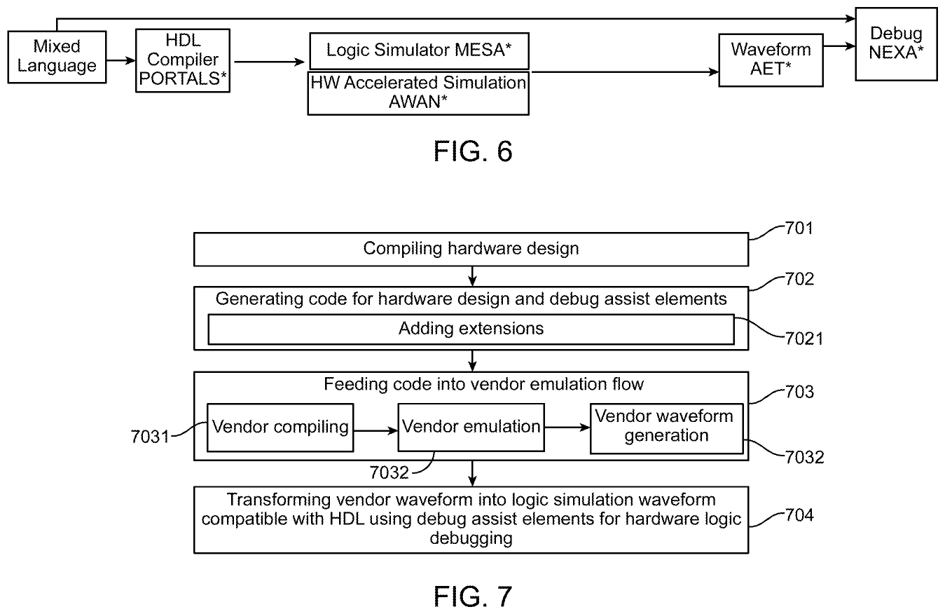

With reference to FIG. 6, platforms for collaborative hardware logic design and debug across design flows are available. In a common logic debug use-case, a hardware RTL is verified using a complementary set of simulation, formal and emulation frameworks. This generates debug data over time in a consistent binary format. As shown in FIG. 6, a hardware design that is coded in VHDL/Verilog is compiled and then simulated to produce logic simulation waveforms for hardware logic debugging. For faster time-to-market of next generation systems, however, the platforms still need to be able to enable “plug-ins” of offerings from vendor companies (i.e., for faster co-debug of hardware/firmware and/or for emulation engine, RISCV-based designs), which is often not possible. In addition, the platforms need to be more flexible and scalable for broader use-cases, while enabling highly efficient system logic debug.

Turning now to an overview of the aspects of the invention, one or more embodiments of the invention address shortcomings of the above-described approaches by providing for a computer-implemented method for aspect-oriented co-debug of simulation traces from different simulators, emulators, post-silicon debug for mixed language (VHDL/Verilog/other) and mixed levels of abstraction designs. In addition, emulation waveform instrumentation techniques for debug assist elements are provided to enable the preservation of original RTL designs, “high-level signal types” and like information for enumeration and state debug. Also, instrumentation correlation to debug information is provided from post-synthesis netlist verilog to pre-synthesis VHDL.

The above-described aspects of the invention address the shortcomings of known approaches by providing for a computer-implemented method for instrumentation-assisted debugging. The computer-implemented method includes compiling a hardware design to generate a compiled design, generating, from the compiled design, code for the hardware design and debug assist elements, feeding the code into a vendor emulation flow that outputs a vendor waveform and transforming the vendor waveform into a logic simulation waveform compatible with a hardware design language (HDL) using the debug assist elements for hardware logic debugging.

Thus, with reference to FIG. 7, a computer-implemented method 700 for instrumentation-assisted debugging is provided. The computer-implemented method 700 includes compiling a hardware design, which can be produced from various mixed language sources, to generate a compiled design by an RTL compiler (block 701). The code for the hardware design can be a hardware description language (HDL) code, such as VHDL or Verilog™. The computer-implemented method 700 further includes generating, from the compiled design, code for the hardware design and debug assist elements (block 702), feeding the code into a vendor emulation flow that outputs a vendor waveform (block 703) and transforming the vendor waveform into a logic simulation waveform compatible with a hardware design language (HDL) using the debug assist elements for hardware logic debugging (block 704). The debug assist elements can be generated by adding one or more extensions to a platform for executing the computer-implemented method (block 7021), with the one or more extensions being configured to extract and store type information that can be augmented into the logic simulation waveform. In accordance with one or more embodiments of the present invention, the vendor emulation flow can include one or more of a vendor compiling operation 7031, a vendor emulation operation 7032 and a vendor waveform generation operation 7034 of one vendor or, in some cases, multiple vendors.

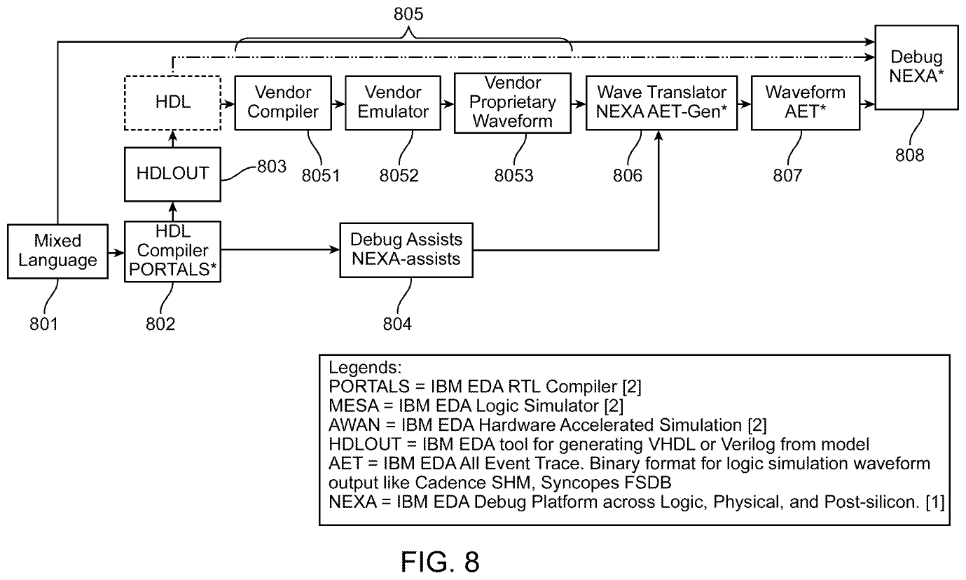

With reference to FIG. 8, a graphical flow diagram is provided to illustrate an operation of the computer-implemented method 700 of FIG. 7. As shown in FIG. 8, mixed language source code 801 is combined and compiled in an HDL compiler 802. The HDL compiler 802 outputs a compiled design that is sent to a plug-in component 803 and from which debug assist elements 804 are generated. The plug-in component 803 generates code for the hardware design, which is fed into vendor emulation flow 805 that in turn output a vendor waveform. The vendor emulation flow 805 is unique for each vendor and can include a vendor compiler 8051, a vendor emulator 8052 and a vendor waveform generator 8053. The vendor waveform is output to wave translator 806, which is receptive of the debug assist elements 804 to generate waveform 807 for use in debug operations 808.

In an operational scenario, a hardware RTL can be a given VHDL along with notable portions of design based on Verilog TM. A main simulation framework can be based on a given logic simulator, complemented with hardware-accelerated simulation capability to generate simulation waveforms. Since debug operations for select complex and full-system level scenarios requires fast interoperation of hardware/firmware system components, emulation platforms from vendors can be used as additional engines to complement hardware verification. Verilog TM code, for example, is generated using the plug-in component 803 and is fed into the vendor emulation flow 805 for specific hardware/firmware co-debug use cases. Waveforms generated in vendor proprietary form are transformed into original HDL-friendly waveforms by the wave translator 806, with additional instrumentation assists from the debug assist elements 804, using a set of new plug-ins. Techniques described herein allow for the provision of plug-ins to stitch together traces, irrespective of where they come from and connect them efficiently for the entire design, no matter what language or level of abstraction portions of the design were written in so that debug information can be mixed, matched and correlated. In addition, instrumentation techniques described herein enable the preservation of original RTL/VHDL designs of “high-level signal type” features and like information. This is a key element for debugging and presents logic designers debug data in a form they can directly relate to for fast debugging. Also, the preservation of enumeration/state debug features enable debug instrumentation assists as well as new extensions to be added which can extract and then store “type” information, which is then augmented into a final waveform.

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” may be understood to include any integer number greater than or equal to one, i.e. one, two, three, four, etc. The terms “a plurality” may be understood to include any integer number greater than or equal to two, i.e. two, three, four, five, etc. The term “connection” may include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A computer-implemented method for instrumentation-assisted debugging, the computer-implemented method comprising:
compiling a hardware design to generate a compiled design;
generating, from the compiled design, code for the hardware design and debug assist elements;
feeding the code into a vendor emulation flow that outputs a vendor waveform; and
transforming the vendor waveform into a logic simulation waveform compatible with a hardware design language (HDL) using the debug assist elements for hardware logic debugging.

2. The computer-implemented method according to claim 1, wherein the hardware design is generated from mixed-language sources.

3. The computer-implemented method according to claim 1, wherein the compiling is executed by a register transfer level (RTL) compiler.

4. The computer-implemented method according to claim 1, wherein the code for the hardware design is a hardware description language (HDL).

5. The computer-implemented method according to claim 1, wherein the vendor emulation flow comprises a vendor compiling operation, a vendor emulation operation and a vendor waveform generation operation of multiple vendors.

6. The computer-implemented method according to claim 1, wherein the generating of the debug assist elements comprises adding one or more extensions to a platform for executing the computer-implemented method.

7. The computer-implemented method according to claim 6, wherein the one or more extensions are configured to extract and store type information that can be augmented into the logic simulation waveform.

8. A computer program product for instrumentation-assisted debugging, the computer program product comprising one or more computer readable storage media having computer readable program code collectively stored on the one or more computer readable storage media, the computer readable program code being executed by a processor of a computer system to cause the computer system to perform a method comprising:
compiling a hardware design to generate a compiled design;
generating, from the compiled design, code for the hardware design and debug assist elements;
feeding the code into a vendor emulation flow that outputs a vendor waveform; and
transforming the vendor waveform into a logic simulation waveform compatible with a hardware design language (HDL) using the debug assist elements for hardware logic debugging.

9. The computer program product according to claim 8, wherein the hardware design is generated from mixed-language sources.

10. The computer program product according to claim 8, wherein the compiling is executed by a register transfer level (RTL) compiler.

11. The computer program product according to claim 8, wherein the code for the hardware design is a hardware description language (HDL).

12. The computer program product according to claim 8, wherein the vendor emulation flow comprises a vendor compiling operation, a vendor emulation operation and a vendor waveform generation operation of multiple vendors.

13. The computer program product according to claim 8, wherein the generating of the debug assist elements comprises adding one or more extensions to a platform.

14. The computer program product according to claim 13, wherein the one or more extensions are configured to extract and store type information that can be augmented into the logic simulation waveform.

15. A computing system comprising:
a processor;
a memory coupled to the processor; and
one or more computer readable storage media coupled to the processor, the one or more computer readable storage media collectively containing instructions that are executed by the processor via the memory to cause the processor to perform steps for instrumentation-assisted debugging comprising:
compiling a hardware design to generate a compiled design;
generating, from the compiled design, code for the hardware design and debug assist elements;
feeding the code into a vendor emulation flow that outputs a vendor waveform; and
transforming the vendor waveform into a logic simulation waveform compatible with a hardware design language (HDL) using the debug assist elements for hardware logic debugging.

16. The computing system according to claim 15, wherein the hardware design is generated from mixed-language sources.

17. The computing system according to claim 15, wherein the compiling is executed by a register transfer level (RTL) compiler.

18. The computing system according to claim 15, wherein the code for the hardware design is a hardware description language (HDL).

19. The computing system according to claim 15, wherein the vendor emulation flow comprises a vendor compiling operation, a vendor emulation operation and a vendor waveform generation operation of multiple vendors.

20. The computing system according to claim 15, wherein:
the generating of the debug assist elements comprises adding one or more extensions to a platform, and
the one or more extensions are configured to extract and store type information that can be augmented into the logic simulation waveform.
